(19) United States
(12) Patent Application Publication
(10) Pub. No.: US 2008/0237843 A1
(43) Pub. Date: Oct. 2, 2008

(54) Microelectronic package including thermally conductive sealant between heat spreader and substrate

(76) Inventors: Ashish Gupta, Chandler, AZ (US); Leonel R. Arana, Phoenix, AZ (US); David Song, Chandler, AZ (US); Chia-Pin Chiu, Tempe, AZ (US); Ravi Prasher, Mesa, AZ (US); Chris Matayabas, Chandler, AZ (US); Nirupama Chakrapani, Chandler, AZ (US)

Correspondence Address: INTEL CORPORATION;c/o INTELLEVATE, LLC, P.O. BOX 52050, MINNEAPOLIS, MN, 55402, US

(21) Appl. No.: 11/729,079

(22) Filed: Mar. 27, 2007

(51) Int. Cl. H01L 23/367; H01L 21/58

(52) U.S. Cl. 257/713; 438/122; 257/E23.104; 257/E21.499

(57) ABSTRACT

A microelectronic package. The package includes a substrate; a die mounted onto the substrate; an integrated heat spreader mounted onto the substrate, and thermally coupled to a backside of the die; and a sealant material bonding the integrated heat spreader to the substrate, the sealant material having a bulk thermal conductivity above about 1 W/m/° C. and a modulus of elasticity lower than a modulus of elasticity of solder.

### FIELD

Embodiments of the present invention relate generally to the field of microelectronic fabrication. More specifically, embodiments of the present invention relate to microelectronic packages including integrated heat spreaders.

### BACKGROUND

FIG. 1 shows a prior art integrated circuit (IC) package 10, which includes a substrate or die carrier 12 with the IC die 14 mounted thereon. An underfill (not shown), used for mechanical support and electrical insulation, may be interposed between the IC die 14 and the die carrier 12. An integrated heat spreader (IHS) lid 18 is mounted to the die carrier 12 by way of a sealant 20. A thermal interface material (TIM) 22 bonds the IC die 14 and the IHS lid 18 together for heat removal. FIG. 1 also shows a variety of heat generating components other than the IC die 14 on the substrate, including an On-Package-Voltage-Regulation device, or OPVR 20, an Integrated Semiconductor Voltage Regulator or ISVR 23 and a Dynamic Random Access Memory or DRAM 24. The package 10 is shown as having been socketed onto a socket 25 including socket pins 26 contacting corresponding contact pads (not shown) of the substrate. During operation, the substrate is heated by a number of sources, including the IC die 14, the other heat generating components thereon including OPVR 20, ISVR 23 and DRAM 24. In addition, simple resistive heating of the substrate from the electrical conduction in the copper traces (not shown) on the substrate can be significant. As package densities decrease and performance speed increases, the amount of heat generated per square inch of the substrate may increase accordingly, thus affecting the performance of the package as a whole. Currently, a scaling back of the substrate electrical currents is being contemplated as a way to address the problems associated with substrate heating, but this at the expense of performance. In addition, current technology is investigating several types of architectures in which additional active devices, such as voltage regulator components, Northbridge memory controllers, memory devices, etc, are integrated on or within the same substrate on to which the CPU is assembled. For many of these devices, the heat generated during operation can be in the tens of Watts. As a result, the prior art has contemplated thermally coupling these devices to the integrated heat spreader of the package through a TIM. However, such an arrangement would severely limit flexibility in terms of the placement of such devices, which must be placed under the IHS lid, and would add additional technical challenges and cost, in the form of the need for backside metallization deposition, indium TIM's, etc.

The prior art further contemplates using a sealant, such as sealant 20 of FIG. 1, which comprises solder, in a package where the substrate includes a thermally conductive core, such as a copper core, as opposed to an organic core, the arrangement thus being adapted to conduct heat away from the substrate. However, disadvantageously, where solder is used as the IHS sealant material, the substrate, be it an organic substrate or a ceramic substrate, and, in addition, the IHS lid, are subject to design constraints in that the surfaces thereof adapted to be sealed must be designed to be wettable by the solder of the sealant material.

In addition, disadvantageously, the prior art does not provide a way of effectively transferring heat away from organic substrates or microelectronic packages. Organic substrates tend to have a higher coefficient of thermal expansion compared to ceramic substrates that may result in higher stresses in the die, underfill and solder bumps. If the substrate is an organic substrate and the sealant material to the IHS is also made of solder as contemplated by the prior art, the above stresses would then extend to the sealant material as well, possibly causing sealant cracking and/or delamination. Organic substrates are known to be desirable by virtue of their lower cost, easier processability, and capacity for a higher I/O as compared with a ceramic substrate.

Disadvantageously the prior art does not allow design flexibility when the IHS sealant is made of solder, and further does not provide a way of addressing heat removal from an organic substrate or die carrier. The prior art packages tend to present increased heating in the area of the socket pins for organic substrates. Given that the socket maximum allowable current per pin (IMAX) is limited by the socket's contact temperature, which in turn is a function of the-substrate's temperature, unaddressed heating of the substrate can result in lower current capability of the socket. Although the prior art has attempted to address the latter problem by increasing the number of socket pins per socket, such a solution disadvantageously leads to larger package form factors and higher cost per package and socket.

### BRIEF DESCRIPTION OF THE DRAWINGS

FIG. 1 is a cross-sectional view of a microelectronic package according to the prior art;

FIG. 2 is a cross-sectional view of a microelectronic package according to an embodiment;

FIG. 3 is a schematic view of a system including a microelectronic package similar to the package of FIG. 2.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic package, a method of forming the package, and a system incorporating the package are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to Figs. X/Y showing an element A/B, what is meant is that Fig. X shows element A and Fig. Y shows element B.

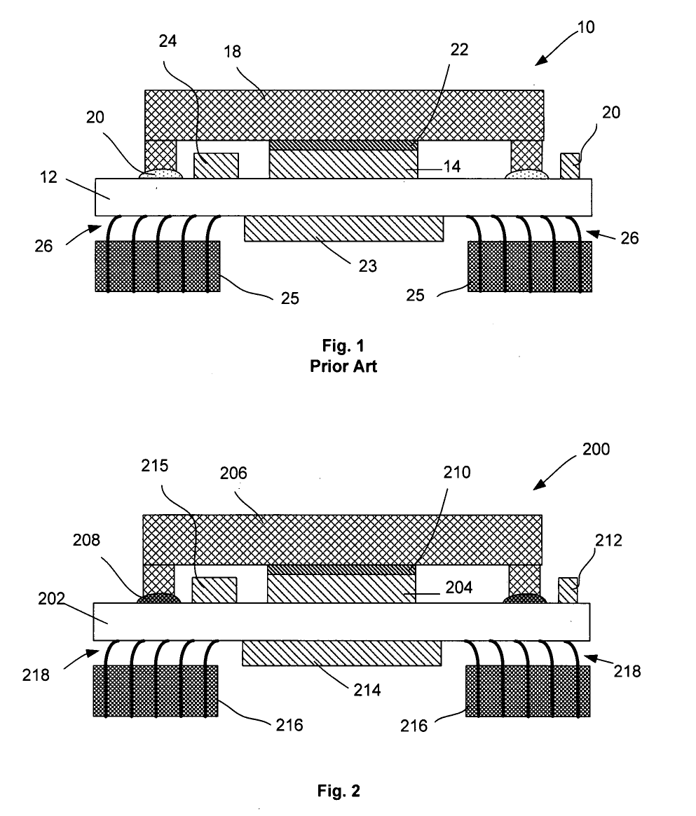

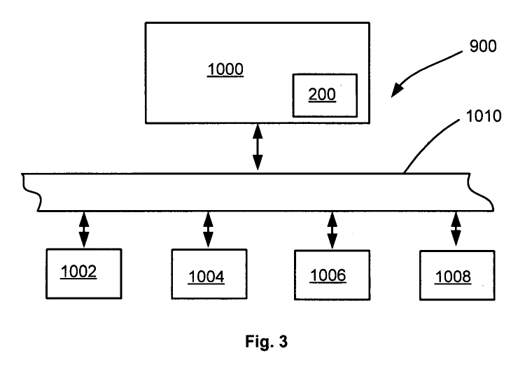

Aspects of this and other embodiments will be discussed herein with respect to FIGS. 2 and 3, below. The figures, however, should not be taken to be limiting, as they are intended for the purpose of explanation and understanding.

Reference is first made to FIG. 2, which shows an integrated circuit (IC) package 200 according to one embodiment. Package 200 includes a substrate 202 with the IC die 204 mounted thereon. The substrate 202 is a conventional substrate, and may include, for example, an organic substrate or a ceramic substrate. In the shown embodiment, die 204 may be flip chip mounted onto the substrate in a well known manner, with or without the use of an underfill material. An integrated heat spreader 206 is mounted to the substrate 202 by way of a sealant material 208. According to embodiments, the sealant material 208 has a bulk thermal conductivity above about 1 W/m/° C. In addition, the sealant, post-cure, is mechanically compatible with both the substrate and the material of the IHS lid such that, during operation when heat generating components on the substrate 202 generate heat, the sealant material 208 is adapted to withstand stresses caused by differential expansions between the substrate 202 and IHS 206 by virtue of their mismatched coefficients of thermal expansions (CTE's). The ability of IHS sealant 208 to withstand stresses as noted above is a function, among others of its modulus of elasticity. Embodiments contemplate an IHS sealant having a modulus of elasticity lower than a modulus of elasticity of solder. According to one embodiment, the sealant material 208 has an elastic modulus less than about 500 MPa, and, preferably, less than about 100 MPa, and more preferably less than about 20 MPa. However, embodiments contemplate the use of sealant materials having a modulus of elasticity higher than 500 MPa. Typically, an organic substrate may have a CTE of about 18-20 ppm/° C., while the IHS may have a CTE of about 16-17 ppm/° C. Thus, during operation, the substrate may expand more than the IHS. However, using a sealant material 208 that is mechanically compatible with both substrate 202 and IHS 206 would withstand stresses caused by the above according to embodiments. A thermal interface material 210 may be used to bond the die 204 and the IHS 206 together for heat removal in a well known manner. FIG. 2 also shows a variety of heat generating microelectronic components other than the die 204 on the substrate, including an On-Package-Voltage-Regulation device, or OPVR 212, an Integrated Semiconductor Voltage Regulator or ISVR 214 and a Dynamic Random Access Memory or DRAM 214. It is noted that the shown configuration of a package including the additional heat generating components shown in FIG. 2 is merely an embodiment, and that embodiments include within their scope any microelectronic substrate onto which at least one heat generating component and an IHS lid have been mounted, or embodiments where other types of heat generating components (i.e. capacitors, chipsets, etc.) and/or other positioning the heat generating components has been effected as compared with the configuration of FIG. 2. The package 200 is shown as having been socketed onto a socket 216 including socket pins 218 contacting corresponding contact pads (not shown) of the substrate. According to embodiments, the sealant material 208 may include a filler material, such as, for example, a metal such as aluminum or silver, or a conductive ceramic material, such as, for example, alumina, aluminum nitride and silicon carbide. The amount of filler in the sealant material would be a function, among others, of a desired bulk thermal conductivity of the sealant material, and, in addition, of a resultant viscosity of the sealant material pre-cure. In particular, the amount of the filler is preferably such that the sealant material pre-cure is dispensable onto the substrate for the purpose of allowing a mounting of the IHS thereto. Preferably, the filler concentration by weight is up to about 90%. The sealant material 208 may be obtained by using a PDMS (poly dimethyl siloxane) resin with roughly 50% loading by weight of filler as described above. In the alternative, the sealant material 208 may comprise a thermally conductive adhesive, such as, for example, thermally conductive adhesives available from the Dow Corning Company, also loaded with roughly from about 50% to about 90% loading by weight of filler. Examples of such adhesives include Dow Corning 1-4173 Thermally Conductive Adhesive, Dow Corning 1-4174 Thermally Conductive Adhesive, Dow Corning 3-1818 Thermally Conductive Adhesive. Where the sealant material 208 is an adhesive with filler, it may, according to an embodiment, have a bulk thermal conductivity between about 1 and about 4 W/m/° C., or a bulk thermal conductivity between about 4 and about 6 W/m/° C.

Advantageously, embodiments provide a thermally conductive sealant between a substrate and the integrated heat spreader of a microelectronic package, in this manner greatly enhancing heat rejection from the substrate and from active devices on or embedded in the substrate that are not thermally coupled to the IHS with a TIM. It has been observed that as the conductivity of the sealant material rises above about 0.5 W/m/° C., not only is there a reduction in the temperature of the substrate hot spot, but also, the location of the substrate hot spot tends to move away from the socket pin region to the center of the socket cavity. Thus, the current capability of a given socket may be raised as compared with an arrangement where the sealant material does not include a thermally conductive material. In addition, to the extent that the sealant material according to embodiments provides a heat transfer path for the heat energy. within the substrate, the microelectronic components on or embedded in the substrate as a result remain cooler, and thus exhibit improved performance.

Moreover, embodiments advantageously provide an IHS sealant that, contrary to solder as sometimes used in the prior art, does not place design and material constraints on the substrate and on the IHS lid. To the extent that embodiments contemplate the use of a material other than solder, such as, for example, a polymeric, thermally conductive adhesive, embodiments do not necessitate a control of properties of surfaces of the substrate and of the IHS lid so as to make those surfaces solder wettable.

Additionally, advantageously, embodiments allow the use of an IHS sealant that can accommodate higher CTE mismatches between the substrate and the IHS lid than solder, by virtue of having a modulus of elasticity lower than that of solder. Thus, embodiments provide a microelectronic package that exhibits improved heat dissipation from a substrate through the IHS sealant material, while at the same time ensuring mechanical compatibility (and hence obviating stress induced cracking, delamination) between the sealant material and both the substrate and the IHS lid. Where the substrate is an organic substrate, mechanical compatibility is even more of a concern by virtue of the more appreciable CTE mismatch between the material of the substrate and that of the IHS lid.

In addition, according to embodiments, the IHS sealant used advantageously provides higher thermal stability than solder which is sometimes used as the IHS sealant in the prior art. First, an IHS sealant according to embodiments may bond at a much lower temperature (such as, for example, at room temperature) than solder, in this way advantageously providing a less costly and less complicated thermally conductive IHS sealant than solder, which requires reflow in order to effect bonding. Second, an IHS sealant according to embodiments is more stable at higher temperatures than solder. While solder may start melting at a temperature equal to or above 180 degrees Celsius, an IHS sealant according to embodiments may not have a melting temperature, glass transition, nor substantially flow or decompose between about room temperature and about 300 degrees Celsius. Thus, an IHS sealant according to embodiments may advantageously be more stable at higher temperatures than solder used as the IHS sealant.

Referring to FIG. 3, there is illustrated one of many possible systems 900 in which embodiments of the present invention may be used. In one embodiment, the electronic assembly 1000 may include a microelectronic package such as package 200 of FIG. 2. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 3, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic package comprising:
a substrate;
a die mounted onto the substrate;
an integrated heat spreader mounted onto the substrate, and thermally coupled to a backside of the die;
a sealant material bonding the integrated heat spreader to the substrate, the sealant material having a bulk thermal conductivity above about 1 W/m/° C. and a modulus of elasticity lower than a modulus of elasticity of solder.

2. The package of claim 1, wherein the sealant material has a modulus of elasticity below about 500 MPa.

3. The package of claim 1, wherein the sealant material includes a filler material.

4. The package of claim 3, wherein the filler material comprises at least one of a metal and a conductive ceramic material.

5. The package of claim 3, wherein the filler material comprises at least one of alumina, aluminum nitride and silicon.

6. The package of claim 1, wherein the sealant material comprises an adhesive.

7. The package of claim 1, wherein the sealant material has a bulk thermal conductivity between about 1 W/m/° C. and about 6 W/m/° C.

8. The package of claim 1, wherein the IHS sealant has a melting point between about room temperature and about 300° C.

9. The package of claim 8, wherein the second microelectronic component is at least one of a voltage regulation device, a memory device, a memory controller, a capacitor and a chipset.

10. A method of fabricating a microelectronic package comprising:
providing a substrate;
mounting a die to the substrate;
thermally coupling an integrated heat spreader to the die;
bonding the integrated heat spreader to the substrate using a sealant material having a bulk thermal conductivity above about 1 W/m/° C. and a modulus of elasticity lower than a modulus of elasticity of solder.

11. The method of claim 10, wherein the sealant material includes a filler material.

12. The method of claim 11, wherein the filler material comprises at least one of a metal and a conductive ceramic material.

13. The method of claim 10, wherein the sealant material has a modulus of elasticity below about 500 MPa.

14. A system comprising:
an electronic assembly including:
a microelectronic package comprising:
a substrate;
a die mounted onto the substrate;
an integrated heat spreader mounted onto the substrate, and thermally coupled to a backside of the die;
a sealant material bonding the integrated heat spreader to the substrate, the sealant material having a bulk thermal conductivity above about 1 W/m/° C. and being adapted to withstand stresses caused by differential expansions between the substrate and the integrated heat spreader during operation; and
a main memory coupled to the electronic assembly.

15. The system of claim 14, wherein the sealant material has a modulus of elasticity below about 500 MPa.
